(19) United States
(12) Patent Application Publication
(10) Pub. No.: US 2024/0324137 A1
(43) Pub. Date: Sep. 26, 2024

(54) COOLING DEVICE, LIGHT SOURCE DEVICE, AND IMAGE PROJECTION APPARATUS

(71) Applicant: Mayu BANNO, Kanagawa (JP)

(72) Inventor: Mayu BANNO, Kanagawa (JP)

(21) Appl. No.: 18/607,623

(22) Filed: Mar. 18, 2024

(30) Foreign Application Priority Data
Mar. 23, 2023 (JP) 2023-047209

(51) Int. Cl. H05K 7/20; F21V 29/503; F21V 29/67; F21V 29/76; H04N 9/31

(52) U.S. Cl. CPC H05K 7/20172; F21V 29/503; F21V 29/673; F21V 29/677; F21V 29/76; H04N 9/3144; H05K 7/20145; H05K 7/20409

(57) ABSTRACT

A cooling device includes a rotator including a heat generation portion to generate heat, and a rotation axis around which the heat generation portion rotates, multiple heat receiving fins each having a heat receiving face extending in an axial direction of the rotation axis of the rotator, and a storage case storing the rotator and the multiple heat receiving fins. The multiple heat receiving fins are on an inner face of the storage case and arrayed in an array direction orthogonal to the axial direction.

### CROSS-REFERENCE TO RELATED APPLICATIONS

This patent application is based on and claims priority pursuant to 35 U.S.C. § 119(a) to Japanese Patent Application No. 2023-047209, filed on Mar. 23, 2023, in the Japan Patent Office, the entire disclosure of which is hereby incorporated by reference herein.

### BACKGROUND

### Technical Field

Embodiments of the present disclosure relate to a cooling device, a light source device, and an image projection apparatus.

### Related Art

In the related art, a cooling device is known that exhausts heat received by multiple heat receiving fins disposed at an inner face of a storage case that accommodates a rotator having a heat generation portion to the outside of the storage case.

In the cooling device described above, multiple heat receiving fins extending in a perpendicular direction from the inner face of the storage case are arranged in a rotation axis direction of the rotator.

### SUMMARY

According to an embodiment of the present disclosure, a cooling device includes a rotator including a heat generation portion to generate heat, and a rotation axis around which the heat generation portion rotates, multiple heat receiving fins each having a heat receiving face extending in an axial direction of the rotation axis of the rotator, and a storage case storing the rotator and the multiple heat receiving fins. The multiple heat receiving fins are on an inner face of the storage case and arrayed in an array direction orthogonal to the axial direction.

According to an embodiment of the present disclosure, a light source device includes a light source to emit a light beam, a rotator including a heat generation portion, a storage case storing the light source and the rotator, and the cooling device to cool an inside of the storage case.

According to an embodiment of the present disclosure, an image projection apparatus includes the light source device, a light homogenizer to homogenize the light beam emitted from the light source device, an image display element to modify the light beam emitted from the light homogenizer and to form an image, and a projection optical system to magnify the image and project the image to a projection face.

### BRIEF DESCRIPTION OF THE DRAWINGS

A more complete appreciation of the disclosure and many of the attendant advantages and features thereof can be readily obtained and understood from the following detailed description with reference to the accompanying drawings, wherein:

FIG. 1 is a diagram of an inner configuration of an image projection apparatus according to an embodiment of the present disclosure;

FIG. 2 is a schematic cross-sectional view of a light source device as viewed from the bottom;

FIG. 3 is an A-A sectional view of FIG. 2;

FIG. 4 is a diagram illustrating airflow flowing on a face of a phosphor wheel of a light source unit when the phosphor wheel is rotated;

FIG. 5 is a schematic diagram illustrating a first modification;

FIG. 6 is a schematic diagram illustrating a configuration in which a fan is disposed near both multiple first heat receiving fins and multiple second heat receiving fins;

FIG. 7 is a schematic diagram illustrating a second modification;

FIG. 8 is a schematic diagram illustrating a third modification;

FIG. 9 is a schematic diagram illustrating a configuration including a first case heat receiving unit and a second case heat receiving unit in the third modification;

FIG. 10 is a schematic diagram illustrating a fourth modification; and

FIG. 11 is a diagram illustrating a hardware configuration of an image projection apparatus.

The accompanying drawings are intended to depict embodiments of the present invention and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

According to embodiments of the present disclosure, the heat receiving efficiency can be increased.

Embodiments of the present disclosure will be described with reference to the drawings. It is easy for a person skilled in the art to make other embodiments by changing and modifying the embodiments of the present disclosure within the scope of the claims, and these changes and modifications are included in the scope of the claims. In the following description, the embodiments of the present disclosure are examples of the best mode of the disclosure and are not intended to limit the scope of the claims.

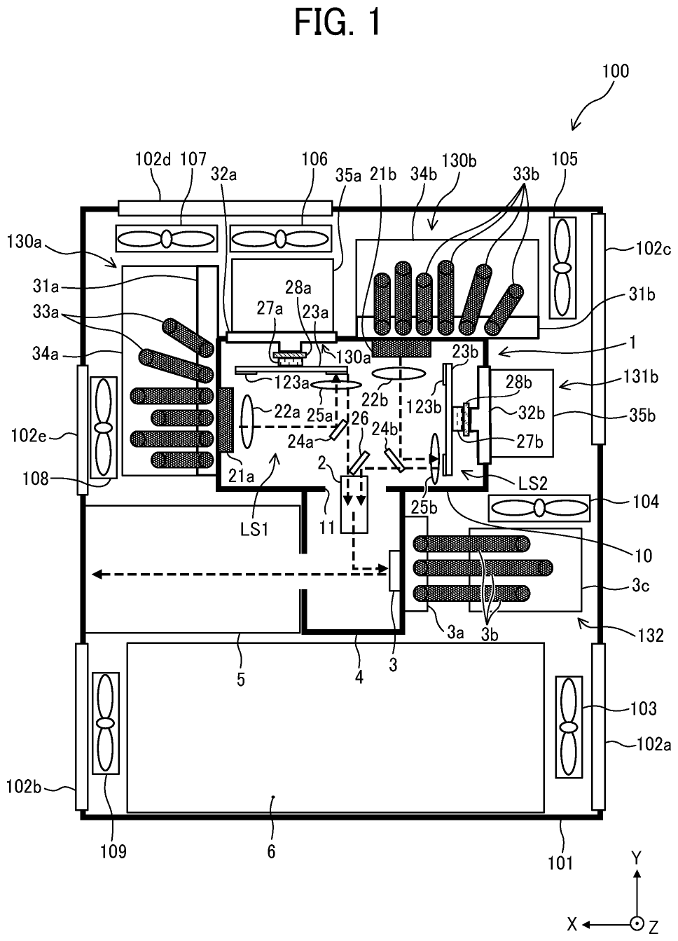

FIG. 1 is a diagram of an inner configuration of an image projection apparatus 100 according to an embodiment of the present disclosure. In the following drawings, the X-direction, the Y-direction, and the Z-direction are directions perpendicular to each other, the X-direction and the Y-direction are horizontal directions, and the Z-direction is a vertical direction. As illustrated in FIG. 1, the image projection apparatus 100 includes a light source device 1, a light tunnel 2 serving as a light homogenizing element, and a digital micromirror device (DMD) 3 serving as an image display element that modulates a light beam from the light tunnel 2 to form an image. The image projection apparatus 100 includes an illumination optical unit 4 that guides the light beam emitted from the light tunnel 2 to the DMD 3. The image projection apparatus 100 further includes a projection optical unit 5 serving as a projection optical system that projects a light beam spatially modulated by the DMD 3 to a projection face as an enlarged image, and an electronic board 6 that controls the image projection apparatus 100.

In an embodiment of the present disclosure, an image projection apparatus includes the light source device, a light homogenizer to homogenize the light beam emitted from the light source device, an image display element to modify the light beam emitted from the light homogenizer and to form an image, and a projection optical system to magnify the image and project the image to a projection face.

The DMD 3 generates an image from the light beam emitted from the light source device 1 by reflecting the light beam that enters the DMD 3 with micromirrors disposed on the face of the DMD 3. The DMD 3 is attached to the illumination optical unit 4. In an embodiment of the present disclosure, the DMD 3 is used as the image display element, but a transmissive liquid crystal element, or a reflective liquid crystal element may be used as the image display element.

The projection optical unit 5 is disposed at a downstream of the optical path from the DMD 3 and is an optical unit serving as a projection unit to project an image to a screen serving as a projection face. The illumination optical unit 4 is an optical unit to guide the light beam that has passed through the light tunnel 2 to the DMD 3. The projection optical unit 5 and the illumination optical unit 4 include optical elements including lenses and mirrors. The illumination optical unit 4 may also include a color wheel that divides the light beam that has passed through the light tunnel 2 into a red color beam, a blue color beam, a green color beam, and a yellow color beam with time division. The color wheel may be disposed between the light tunnel 2 and the light source device 1, and the time-divided beams, i.e., the red color beam, the blue color beam, the green color beam, and the yellow color beam may enter the light tunnel 2.

The light source device 1 includes a first light source unit LS1 and a second light source unit LS2, and the storage case 10 accommodates the first light source unit LS1 and the second light source unit LS2.

The first (second) light source unit LS1 (LS2) includes a light emitting element 21a (21b), a light source optical system 22a (22b) disposed at a position opposed to the light emitting element 21a (21b), and a dichroic mirror 24a (24b). The first (second) light source unit LS1 (LS2) includes a phosphor wheel 23a (23b) having a disk shape, which is a rotator and serves as a wavelength converter, and a condensing optical system 25a (25b).

The light emitting element 21a (21b) is a multi-chip laser diode unit in which multiple light-emitting portions are arranged on a two-dimensional plane. The light source optical system 22a (22b) includes a collimator lens that converts an excitation light beam emitted from the light emitting portions of the light emitting element 21a (21b) into a parallel light beam (excitation parallel light beam), and a condenser lens that condenses the excitation parallel light beam. The collimator lenses are disposed in an array at a position opposed to the multiple light emitting portions.

The dichroic mirror 24a (24b) reflects only a light beam having a specific wavelength of the light beam that has passed through the light source optical system 22a (22b) to the phosphor wheels 23a (23b). The condensing optical system 25a (25b) condenses a light beam on a predetermined position on the phosphor wheel 23a (23b) to form an irradiation spot.

The phosphor wheel 23a (23b) that is a rotator having a disk shape and functions as a wavelength converter is configured to rotate at high speed by a drive motor 27a (27b). In an embodiment of the present disclosure, the phosphor wheel 23a (23b) includes a phosphor portion 123a (123b) that is a light-receiving-and-heat-generating portion and also a wavelength conversion region to which the phosphor (fluorescent material) is applied, and an excitation light beam reflection portion that is a non-wavelength conversion region to reflect the excitation light beam. Since the phosphor wheel 23a (23b) is rotated, the excitation light beam reflection portion and the phosphor portion 123a (123b) are switched at the position of the irradiation spot.

In an embodiment of the present disclosure, in the light source device, the heat generation portion is a light receiving portion to receive the light beam emitted from the light source to generate heat.

In an embodiment of the present disclosure, in the light source device, the light receiving portion includes a phosphor portion.

In an embodiment of the present disclosure, a blue light beam having a center wavelength of emission intensity of 455 nm is used as the excitation light beam emitted from the light emitting element 21a (21b). Accordingly, when the excitation light beam reflection portion of the phosphor wheel is disposed at the position of the irradiation spot, the blue light beam is emitted as it is without wavelength conversion. On the other hand, when the phosphor portion 123a (123b) is disposed at the position of the irradiation spot, the phosphor portion 123a (123b) converts the wavelength of the blue light beam into a wavelength of a yellow fluorescence light beam or yellow-green fluorescence light beam, and outputs the yellow fluorescence light beam or yellow-green fluorescence light beam.

The light beam reflected by the phosphor wheel 23a (23b) passes through the condensing optical system 25a (25b) again. The light beam from the first light source unit LS1 directly enters the light runnel 2, and the light beam from the second light source unit LS2 is reflected by a folding mirror 26 and enters the light tunnel 2.

A combining prism may be disposed instead of the folding mirror 26. The light beam from the first light source unit LS1 may be transmitted through the combining prism, and the light beam from the second light source unit LS2 may be reflected by the combining prism. The light beam from the first light source unit LS1 and the light beam from the second light source unit LS2 may be combined and enter the light tunnel 2.

The storage case 10 that accommodates the first light source unit LS1, the second light source unit LS2, and other components of the light source device 1 has a rectangular parallelepiped (i.e., cuboid). Among the four side faces of the storage case 10, the side face of the storage case 10 opposed to the illumination optical unit 4 has an opening 11 through which the light tunnel 2 passes. The side face of the storage case 10 opposed to the illumination optical unit 4 is adhered to a case that holds, for example, a lens of the illumination optical unit 4 via, for example, a sponge.

The storage case 10 is made of a metal material such as an aluminum alloy or a magnesium alloy having high thermal conductivity. Since the storage case 10 made of a metal material having high thermal conductivity is used, the heat in the storage case 10 can be dissipated through the storage case 10, and the temperature rise in the storage case 10 can be prevented.

The storage case 10 may have a dustproof function for preventing foreign substances from entering. For example, a dustproof material having air permeability such as a dustproof sponge is used, and gaps between multiple parts included in the storage case 10 are filled with the dustproof material. Accordingly, both the dustproof effect and the effect of pressure fluctuation absorption are preferably achieved.

A second light source heat receiving plate 31b of a second light source cooling unit 130b that receives the heat of the light emitting element 21b of the second light source unit LS2 is attached to a side face opposite the side face opposed to the illumination optical unit 4 of the storage case 10. The second light source heat receiving plate 31b will be described below. A first motor heat receiving plate 32a of the first motor cooling unit 131a (i.e., motor cooler) that receives the heat of the drive motor 27a that rotates and drives the phosphor wheel 23a of the first light source unit LS1 is also attached to this side face to which the second light source heat receiving plate 31b is attached.

A second motor heat receiving plate 32b of a second motor cooling unit 131b (i.e., motor cooler) that receives the heat from a drive motor 27b that rotates and drives the phosphor wheel 23b of the second light source unit LS2 is attached to one side face (the right side face of the storage case 10 in FIG. 1) parallel to a direction in which the light beam enters the light tunnel 2 of the storage case 10. The second motor heat receiving plate 32b will be described below.

In an embodiment of the present disclosure, the cooling device further includes a motor to rotate the rotation axis to rotate the rotator and a motor cooler to dissipate heat generated from the motor to an outside of the storage case.

A first light source heat receiving plate 31a that receives the heat from the light emitting element 21a of the first light source unit LS1 is attached to another side face (the left side face of the storage case 10 in FIG. 1) parallel to the direction in which the light beam enters the light tunnel 2 of the storage case 10.

Typically, the light emitting element 21a (21b) has an upper limit of temperature that allows the operation and needs to be cooled below the upper limit temperature. In addition, the light emitting element has a feature in which the light utilization efficiency is decreased with increasing the temperature. The light utilization efficiency is a ratio of the energy used for light output to the power consumption. In order to achieve a light source device having high illuminance, the temperature of the light emitting element is kept lower as much as possible even if the temperature of the light emitting element does not reach the upper limit temperature.

Thus, the light source device 1 according to an embodiment of the present disclosure includes a first light source cooling unit 130a (i.e., cooler) that cools the light emitting element 21a of the first light source unit LS1 and a second light source cooling unit 130b that cools the light emitting element 21b of the second light source unit LS2.

In an embodiment of the present disclosure, the cooling device further includes a light emitter in the storage case to emit light and a cooler to dissipate heat generated from the light emitter to an outside of the storage case.

The first (second) light source cooling unit 130a (130b) includes a first (second) light source heat receiving plate 31a (31b) that receives the heat from the light emitting element 21a (21b), and a light source heat dissipation unit 34a (34b) that dissipates the heat received from the first (second) light source heat receiving plate 31a (31b).

As described above, the first (second) light source heat receiving plate 31a (31b) is attached to the side face of the storage case 10, and the light emitting element 21a (21b) is attached to the first (second) light source heat receiving plate 31a (31b).

The light source heat dissipation unit 34a (34b) is disposed outside the storage case 10 and includes multiple heat dissipation fins having plate shapes. The light source heat dissipation unit 34a (34b) is in thermal contact with the first (second) light source heat receiving plate 31a (31b). Multiple heat pipes 33a (33b) are connected to the first (second) light source heat receiving plate 31a (31b) serving as a heat transportation element that transports the heat of the first (second) light source heat receiving plate 31a (31b) to the multiple heat dissipation fins disposed at a position away from the light source heat receiving plates. The position is, for example, the tip end of the multiple heat dissipation fins of the light source heat dissipation unit. As the heat transportation element, a liquid cooling device that circulates a cooling liquid between the light source heat receiving plate and the multiple heat dissipation fins to transfer the heat of the light source heat receiving plate to the multiple heat dissipation plate fins may be used.

The first (second) light source cooling unit 130a (130b) removes the heat from the light emitting element 21a (21b) and dissipates the heat to the outside of the storage case 10. Thus, the temperature rise of the light emitting element 21a (21b) can be prevented. As a result, a decrease in the light utilization efficiency of the light emitting element 21a (21b) can be preferably prevented.

The phosphor portion 123a (123b) of the phosphor wheel 23a (23b) typically generates heat when receiving the light beam having a wavelength emitted from the light emitting element 21a (21b) and converts the light beam having the wavelength into another light beam having another wavelength. The lower the temperature of the phosphor portion 123a (123b), the higher the light conversion efficiency of the phosphor portion 123a (123b). Thus, the main body (i.e., wheel) of the phosphor wheel 23a (23b) is made of a material having a higher thermal conductivity than the thermal conductivity of the phosphor portion 123a (123b) so that the phosphor portion 123a (123b) does not reach high temperature.

In an embodiment of the present disclosure, in the light source device, the rotator has a wheel made of a material having a thermal conductivity higher than a thermal conductivity of the heat generation portion.

The main body (i.e., wheel) of the phosphor wheel 23a (23b) has a larger face area than the face area of the phosphor portion 123a (123b), and thus has a high heat dissipation efficiency. Accordingly, since the main body (i.e., wheel) of the phosphor wheel 23a (23b) is made of a material having a higher thermal conductivity than the thermal conductivity of the phosphor portion 123a (123b), the heat of the phosphor portion 123a (123b) is preferably conducted, and the heat of the phosphor portion 123a (123b) can be preferably dissipated from the main body (i.e., wheel). As a result, the temperature rise of the phosphor portion 123a (123b) can be prevented, and the decrease in the light conversion efficiency of the phosphor portion 123a (123b) can be prevented.

It is preferable that the edge face (i.e., the face perpendicular to the rotation axis) of the phosphor wheel 23a (23b) is formed in an unevenness shape to increase the face arca and increase the heat dissipation efficiency. Since an uneven shape is formed on the edge face of the phosphor wheel 23a (23b), the following effect can also be obtained. When the phosphor wheel 23a (23b) is rotated, a turbulent flow can be generated near the edge face of the phosphor wheel 23a (23b). The generation of the turbulent flow near the edge face of the phosphor wheel 23a (23b) activates the exchange of air heated by contact with the phosphor wheel 23a (23b) and air having a low temperature and not contacting the phosphor wheel 23a (23b). Accordingly, the phosphor wheel 23a (23b) can be preferably cooled, and the temperature rise of the phosphor portion 123a (123b) can be prevented. As a result, the decrease in the light conversion efficiency of the phosphor portion 123a (123b) can be prevented.

The light source device 1 further includes a first motor cooling unit 131a that cools a drive motor 27a that rotationally drives the phosphor wheel 23a of the first light source unit LS1, and a second motor cooling unit 131b that cools a drive motor 27b that rotationally drives the phosphor wheel 23b of the second light source unit LS2.

The first (second) motor cooling unit 131a (131b) includes the first (second) motor heat receiving plate 32a (32b) that receives the heat from the drive motor 27a (27b) and a motor heat dissipation unit 35a (35b) that dissipates the received heat to the outside of the storage case 10.

As described above, the first motor heat receiving plate 32a and the second motor heat receiving plate 32b are attached to the side face of the storage case 10. The first (second) motor heat receiving plate 32a (32b) is in thermal contact with the motor bracket 28a (28b) that holds the drive motor 27a (27b). The non-rotating portion of the drive motor 27a (27b) is screwed to the motor bracket 28a (28b) and held with the motor bracket 28a (28b).

The motor heat dissipation unit 35a (35b) including multiple heat dissipation fins is in thermal contact with the first (second) motor heat receiving plate 32a (32b). The heat received by the first (second) motor heat receiving plate 32a (32b) is dissipated to the outside of the storage case 10 by the motor heat dissipation unit 35a (35b).

The first (second) motor heat receiving plate 32a (32b) receives the heat from the drive motor 27a (27b) via the motor bracket 28a (28b), and the heat from the drive motor 27a (27b) received by the first (second) motor heat receiving plate 32a (32b) is exhausted to the outside of the storage case 10 by the motor heat dissipation unit 35a (35b). Accordingly, the drive motor 27a (27b) can be cooled so that the temperature of the drive motor 27a (27b) does not rise above the upper limit of the specification.

Further, the DMD 3 includes a DMD cooling unit 132 that dissipates heat generated by the DMD 3 and cools the DMD3. The DMD cooling unit 132 includes a DMD heat receiving plate 3a that receives the heat generated by the DMD 3, and a DMD heat dissipation unit 3c that dissipates the heat received by the DMD heat receiving plate 3a.

The DMD heat receiving plate 3a is attached to the case of the illumination optical unit 4 and is in thermal contact with the DMD 3. The DMD heat dissipation unit 3c includes multiple heat dissipation fins having plate shapes, and is thermally connected to the DMD heat receiving plate 3a via multiple heat pipes 3b serving as heat transportation element.

The exterior case 101 of the image projection apparatus 100 has multiple vents 102a, 102b, 102c, 102d, and 102e. The fans 104, 105, 106, 107, and 108 serving as airflow generators that cool the DMD heat dissipation unit 3c, the light source heat dissipation unit 34a, the light source heat dissipation unit 34b, the motor heat dissipation unit 35a, and the motor heat dissipation unit 35b by air, respectively, are disposed near the DMD heat dissipation unit 3c, the light source heat dissipation unit 34a, the light source heat dissipation unit 34b, the motor heat dissipation unit 35a, and the motor heat dissipation unit 35b, respectively. The exterior case 101 includes the fans 103 and 109 serving as airflow generators that cool the electronic board 6. As described above, since the fans 104, 105, 106, 107, and 108 are disposed near the DMD heat dissipation unit 3c, the light source heat dissipation unit 34a, the light source heat dissipation unit 34b, the motor heat dissipation unit 35a, and the motor heat dissipation unit 35b, respectively, air can be preferably sent to the DMD heat dissipation unit 3c, the light source heat dissipation unit 34a, the light source heat dissipation unit 34b, the motor heat dissipation unit 35a, and the motor heat dissipation unit 35b. As a result, the DMD heat dissipation unit 3c, the light source heat dissipation unit 34a, the light source heat dissipation unit 34b, the motor heat dissipation unit 35a, and the motor heat dissipation unit 35b can be preferably cooled by air. Each of the fans 103 to 109 may be, for example, an axial flow fan or a sirocco fan, but is not limited to an axial flow fan or a sirocco fan.

In an embodiment of the present disclosure, the heat sink having multiple heat dissipation fins is used for each of the DMD heat dissipation unit 3c, the light source heat dissipation unit 34a, the light source heat dissipation unit 34b, the motor heat dissipation unit 35a, and the motor heat dissipation unit 35b to increase the heat transfer area, but the heat dissipation unit is not limited to the heat sink having multiple heat dissipation fins. The heat dissipation fin may be any fin as long as the fin has at least an unevenness shape, and includes a plate fin, a pin fin, and a corrugated fin. Each of the DMD heat dissipation unit 3c, the light source heat dissipation unit 34a, the light source heat dissipation unit 34b, the motor heat dissipation unit 35a, and the motor heat dissipation unit 35b is preferably connected to a part (e.g., heat receiving plate or heat pipe) that receives the heat with a material (e.g., heat conduction grease, heat conduction sheet, or brazing metal) having a higher thermal conductivity than air.

The fans 103, 104, 105, 106, 107, 108, and 109 are disposed near the vents 102a, 102a and 102c, 102c, 102d, 102d, 102e, and 102b, respectively. Air for air cooling is taken in from some of the multiple vents, and the air after air cooling is exhausted from some of the multiple vents. As described above, since the fans 103, 104, 105, 106, 107, 108, and 109 are disposed near the vents 102a, 102a and 102c, 102c, 102d, 102d, 102c, and 102b, respectively, air with a low temperature can be taken in from the outside of the exterior case 101, and air with a risen temperature after cooling can be preferably exhausted. As a result, the temperature rise in the exterior case 101 can be preferably prevented, and the DMD heat dissipation unit 3c, the light source heat dissipation unit 34a, the light source heat dissipation unit 34b, the motor heat dissipation unit 35a, and the motor heat dissipation unit 35b can be preferably cooled by air.

A fan serving as a case cooling device that blows air for cooling the storage case 10 of the light source device 1 may be disposed. Accordingly, the storage case 10 can be cooled by air, and the heat in the storage case 10 can be preferably exhausted from the storage case 10.

In an embodiment of the present disclosure, the cooling device further includes a storage case cooler to blow cool air to the storage case.

When the phosphor portion 123a (123b) serving as the light-receiving-and-heat-generating portion of the phosphor wheel 23a (23b) accommodated in the storage case 10 converts the light beam having a wavelength into another light beam having another wavelength, heat is generated, and the generated heat heats air in the storage case 10. As a result, the temperature in the storage case 10 may rise due to the continuous use of the phosphor wheel 23a (23b), and the temperature in the storage case 10 may reach high temperature. Since the temperature in the storage case becomes high temperature, temperatures of the light emitting elements 21a and 21b and the phosphor wheels 23a and 23b become high. As a result, the light emission efficiency of the light emitting elements 21a and 21b and the light conversion efficiency of the phosphor portions 123a and 123b may be decreased.

As described above, the storage case 10 made of a metal material having high thermal conductivity is used, and the heat in the storage case 10 is dissipated from the storage case 10. However, there is room to reduce the temperature rise in the storage case 10. In an embodiment of the present disclosure, an in-case cooling unit that cools the inside of the storage case 10 is disposed. The in-case cooling unit will be described below with reference to drawings.

In an embodiment of the present disclosure, an image projection apparatus includes the light source device, a light homogenizer to homogenize the light beam emitted from the light source device, an image display element to modify the light beam emitted from the light homogenizer and to form an image, and a projection optical system to magnify the image and project the image to a projection face.

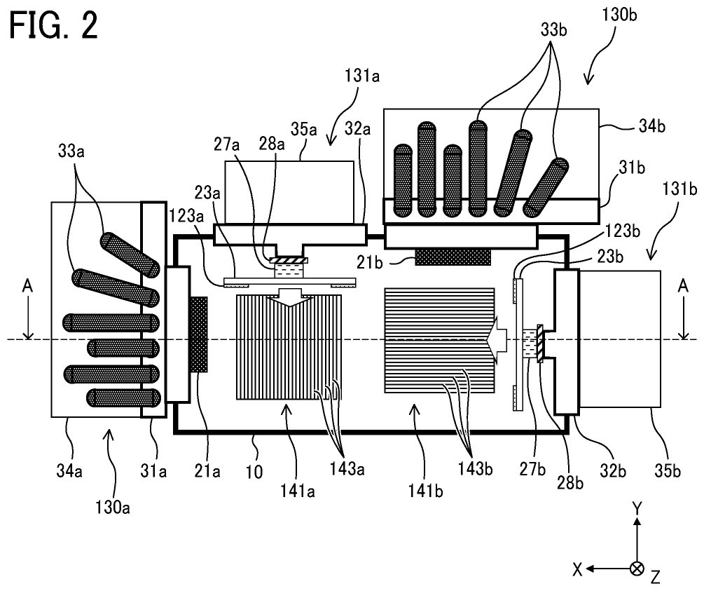

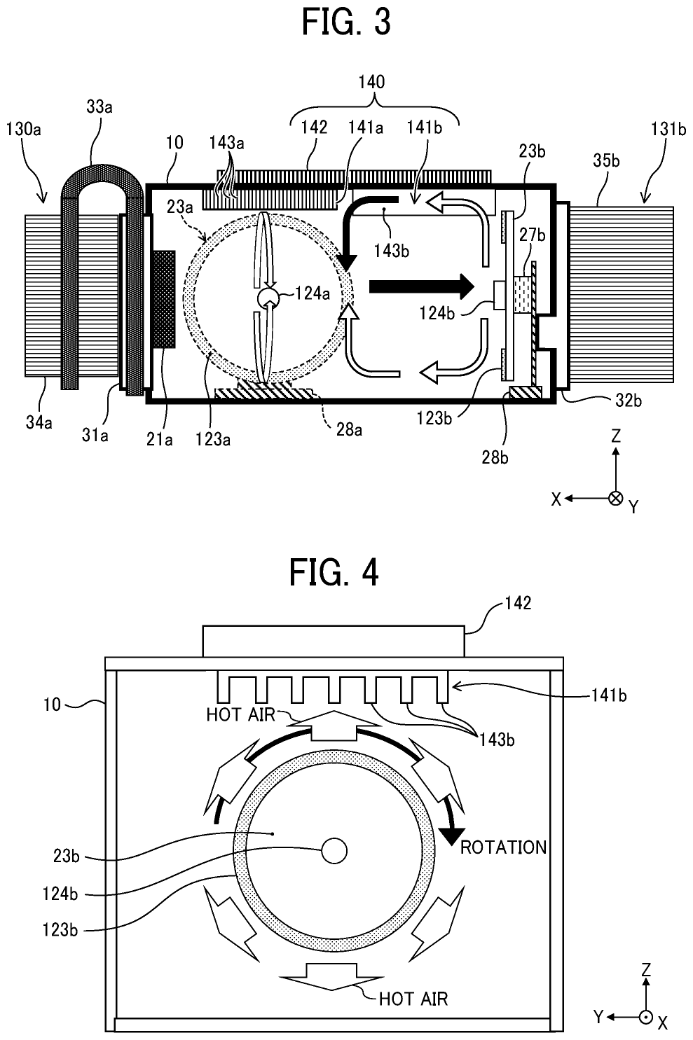

FIG. 2 is a schematic cross-sectional view of the light source device 1 as viewed from the bottom, and FIG. 3 is an A-A sectional view of FIG. 2. FIG. 4 is a diagram illustrating airflow flowing on the edge face of a phosphor wheel 23b when the phosphor wheel 23b of the second light source unit LS2 is rotated. The edge face is a face perpendicular to the rotation axis of the phosphor wheel 23b. In the drawings used in the following description, the components that are not related to cooling, such as the light source optical systems 22a and 22b, may be omitted as appropriate.

As illustrated in FIGS. 2 and 3, the in-case cooling unit 140 includes a first case heat receiving unit 141a, a second case heat receiving unit 141b, and a case heat dissipation unit 142 that dissipates the heat received by the first case heat receiving unit 141a and the second case heat receiving unit 141b to the outside of the storage case 10. The first (second) case heat receiving unit 141a (141b) is disposed on an inner face (referred to as an upper face) of an upper wall of the storage case 10. The first (second) case heat receiving unit 141a (141b) is a heat sink including multiple first (second) heat receiving fins 143a (143b) having plate shapes.

The first (second) case heat receiving unit 141a (141b) may be a separate part from the storage case 10, or may be integrated with the storage case 10 by directly forming the multiple first (second) heat receiving fins 143a (143b) on the upper face of the storage case 10.

The first case heat receiving unit 141a is disposed near the phosphor wheel 23a of the first light source unit LS1. The multiple first heat receiving fins 143a of the first case heat receiving unit 141a perpendicularly extend to the upper face of the storage case 10, and are disposed in a direction perpendicular to a direction of the rotation axis 124a of the phosphor wheel 23a. In the multiple first heat receiving fins 143a, a heat receiving face (i.e., face with a largest area of heat receiving among the multiple faces) is disposed in parallel to the direction of the rotation axis 124a of the phosphor wheel 23a. The rotation axis 124a and the heat receiving face of the multiple first heat receiving fins 143a may not be completely parallel to each other, and the heat receiving face of the multiple first heat receiving fins 143a may be slightly inclined (substantially parallel to each other) with respect to the rotation axis 124a.

In an embodiment of the present disclosure, a cooling device includes a rotator including a heat generation portion to generate heat, and a rotation axis around which the heat generation portion rotates, multiple heat receiving fins each having a heat receiving face extending in an axial direction of the rotation axis of the rotator, and a storage case storing the rotator and the multiple heat receiving fins. The multiple heat receiving fins are on an inner face of the storage case and arrayed in an array direction orthogonal to the axial direction.

In an embodiment of the present disclosure, in the light source device, the multiple heat receiving fins includes: first multiple heat receiving fins each having a first heat receiving face parallel to the first rotation axis of the first rotator; and second multiple heat receiving fins each having a second heat receiving face parallel to the second rotation axis of the second rotator, the first multiple heat receiving fins are disposed on an inner face of the storage case parallel to the first rotation axis of the first rotator, and the second multiple heat receiving fins are disposed on an inner face of the storage case parallel to the second rotation axis of the second rotator.

The second case heat receiving unit 141b is disposed near the phosphor wheel 23b of the second light source unit LS2. The multiple second heat receiving fins 143b of the second case heat receiving unit 141b perpendicularly extend to the upper face of the storage case 10, and are disposed in the direction perpendicular to the direction of the rotation axis 124b of the phosphor wheel 23b. The multiple second heat receiving fins 143b are disposed such that a heat receiving face of the multiple second heat receiving fins 143b is disposed in parallel to the rotation axis 124b of the phosphor wheel 23b in the second light source unit LS2. The rotation axis 124b and the heat receiving face of the multiple second heat receiving fins 143b may not be completely parallel to each other, and the heat receiving face of the multiple second heat receiving fins 143b may be slightly (substantially parallel to each other) inclined to the rotation axis 124b.

In an embodiment of the present disclosure, the rotation axis 124a of the phosphor wheel 23a in the first light source unit LS1 is perpendicular to the rotation axis 124b of the phosphor wheel 23b in the second light source unit LS2. Accordingly, the heat receiving face of the multiple first heat receiving fins 143a is substantially perpendicular to the rotation axis 124b of the phosphor wheel 23b in the second light source unit LS2, and the heat receiving face of the multiple second heat receiving fins 143b is substantially perpendicular to the rotation axis 124a of the phosphor wheel 23a of the first light source unit LS1. In an embodiment of the present disclosure, the multiple first (second) heat receiving fins 143a (143b) are plate fins whose heat receiving face has a flat shape, but may be corrugated fins whose heat receiving face has a wave-shape.

In an embodiment of the present disclosure, in the light source device, the rotator includes: a first rotator including: a first heat generation portion; and a first rotation axis around which the first heat generation portion rotates; and a second rotator including: a second heat generation portion; and a second rotation axis around which the second heat generation portion rotates, the second rotation axis perpendicular to the first rotation axis of the first rotator, and the storage case stores the first rotator and the second rotator.

The case heat dissipation unit 142 is attached to the outer face of the upper wall of the storage case 10, is opposed to the first case heat receiving unit 141a and the second case heat receiving unit 141b across the storage case 10, and is thermally connected to the first (second) case heat receiving unit 141a and the case heat receiving unit 141b via the storage case 10. The case heat dissipation unit 142 is a heat sink having multiple heat dissipation fins. The case heat dissipation unit 142 may be a part separate from the storage case 10, or may be a part integrated with the storage case 10 by directly forming the multiple heat dissipation fins on the outer face of the upper wall of the storage case 10. Further, the storage case 10 may have an opening on the upper wall of the storage case 10, and the case heat dissipation unit 142 may be brought into direct contact with the first case heat receiving unit 141a and the second case heat receiving unit 141b. The multiple heat dissipation fins of the case heat dissipation unit 142 may be any fins as long as the fins have at least an unevenness shape, and for example, plate fins, pin fins, and corrugated fins can be used.

In an embodiment of the present disclosure, the cooling device further includes multiple heat dissipation fins on an outer face of the storage case. The storage case has a wall having the outer face and the inner face opposite to the outer face.

In an embodiment of the present disclosure, the cooling device further includes a motor to rotate the rotation axis to rotate the rotator and a motor cooler to dissipate heat generated from the motor to an outside of the storage case.

In an embodiment of the present disclosure, the first case heat receiving unit 141a and the second case heat receiving unit 141b are disposed on the same face (upper face) of the storage case 10. Accordingly, the heat received by the multiple first heat receiving fins 143a and the heat received by the multiple second heat receiving fins 143b can be exhausted to the outside of the storage case 10 by a single case heat dissipation unit. As a result, the number of parts can be reduced and the cost of the apparatus can be reduced as compared with the case where the first case heat receiving unit 141a and the second case heat receiving unit 141b are disposed on different inner faces of the storage case 10. The first case heat receiving unit 141a and the second case heat receiving unit 141b may be disposed on the bottom face of the storage case 10. The first case heat receiving unit 141a and the second case heat receiving unit 141b may be disposed on the inner face of the storage case 10 parallel (substantially parallel) to the rotation axis directions of both the rotation axis 124a of the phosphor wheel 23a and the rotation axis 124b of the phosphor wheel 23b, or on the inner face that does not intersect with the rotation axis directions.

As illustrated in FIG. 4, since the phosphor wheel 23b of the second light source unit LS2 rotates, the air heated by the phosphor wheel 23b flows radially as hot air along the edge face (the face perpendicular to the rotation axis) of the phosphor wheel 23b. As described above, the heated air (hot air caused by cooling the phosphor wheel) flowing radially hits the inner face of the storage case 10 opposed to the circumferential face (cylindrical face parallel to the rotation axis) of the phosphor wheel 23b. The hot air flows along the inner face in the direction of the rotation axis of the phosphor wheel 23b (see FIG. 3). In FIG. 3, the white arrows indicate the heated air heated by the phosphor wheel, and the black arrows indicate the cooled air cooled by the fins.

Similarly, the heated air heated by the phosphor wheel 23a (i.e., hot air caused by cooling the phosphor wheel 23b) also hits the inner face of the storage case 10 opposed to the circumferential face (cylindrical face parallel to the rotation axis) of the phosphor wheel 23b. The hot air flows along the inner face in the direction of the rotation axis of the phosphor wheel 23b.

The hot air that has hit an inner face opposed to the edge face of the phosphor wheel 23b other than the upper face of the storage case 10 flows along the inner face. In this course, heat is taken away from the hot air by the storage case 10 and the hot air is cooled. The heat taken by the storage case 10 is exhausted to the outside of the storage case 10.

On the other hand, the hot air that has hit the upper face of the storage case 10 flows to the first (second) case heat receiving unit 141a (141b) including the multiple first (second) heat receiving fins 143a (143b) to increase a heat receiving area.

The hot air flows through the spaces between the multiple first (second) heat receiving fins 143a (143b) of the first (second) case heat receiving unit 141a (141b), and the heat of the hot air is taken by the multiple first (second) heat receiving fins 143a (143b). Thus, more heat is taken away from the hot air flowing along the upper face of the storage case 10 than the hot air flowing along the other inner faces opposed to the circumferential face of the phosphor wheel. As a result, the hot air flowing along the upper face of the storage case 10 is more cooled than the hot air flowing along other inner faces. The heat received by the multiple first (second) heat receiving fins 143a (143b) of the first (second) case heat receiving unit 141a (141b) is exhausted to the outside of the storage case 10 by the case heat dissipation unit 142.

As illustrated in FIG. 4, since air flows radially along the edge face of the phosphor wheel 23a (23b), a negative pressure is generated at a space near the rotation axis of the phosphor wheel 23a (23b). Thus, as illustrated in FIG. 3, in the storage case 10, airflow flowing in parallel to the rotation axis 124a (124b) toward the rotation axis 124a (124b). As a result, the negative pressure is generated in an area away from the phosphor wheel 23a (23b) in the direction of the rotation axis. Since the negative pressure is generated in the area away from the phosphor wheel 23a (23b) in the direction of the rotation axis, the cooled air cooled by the first (second) case heat receiving unit 141a (141b) flows into the negative pressure portion. As a result, the cooled air is mixed with the air in the storage case 10, and the temperature of the overall storage case 10 falls.

As described above, in an embodiment of the present disclosure, since the in-case cooling unit 140 is disposed, the temperature rise in the storage case 10 can be prevented as compared with the case where only the storage case 10 exhausts the heat in the case. Accordingly, the temperature rise of the light emitting element 21a (21b) and the temperature rise of the phosphor wheel 23a (23b) can be prevented, and the decrease in the light emitting efficiency of the light emitting element 21a (21b) and the decrease in the light conversion efficiency of the phosphor portion 123a (123b) can be preferably prevented. Thus, a decrease in illuminance of the light beam that enters the light tunnel can be prevented, and a high illuminance image can be projected to the projection face.

In a case where the heat receiving face of the multiple first (second) heat receiving fins 143a (143b) is perpendicular to the rotation axis of the phosphor wheel 23a (23b) disposed near the first (second) heat receiving fins 143a (143b), the multiple first (second) heat receiving fins 143a (143b) may hamper the circulating airflow from flowing in the storage case 10 as illustrated in FIG. 3. As a result, the hot air flowing to the upper face of the storage case 10 may remain in the first (second) case heat receiving unit 141a (141b), and the air in the storage case 10 may not be efficiently cooled by the first (second) case heat receiving unit 141a (141b).

On the other hand, in an embodiment of the present disclosure, since the heat receiving face of the multiple first (second) heat receiving fins 143a (143b) is parallel to the rotation axis 124a (124b) of the phosphor wheel 23a (23b) disposed near the multiple first (second) heat receiving fins 143a (143b), the multiple first (second) heat receiving fins 143a (143b) do not hamper the circulating airflow from flowing in the storage case 10 as illustrated in FIG. 3. Accordingly, the hot air flowing to the upper face of the storage case 10 smoothly flows through the first (second) case heat receiving unit 141a (141b), and the air in the storage case 10 can be efficiently cooled by the first (second) case heat receiving unit 141a (141b). As a result, the temperature rise of the light emitting element 21a (21b) and the temperature rise of the phosphor wheel 23a (23b) can be prevented, and the decrease in the light emitting efficiency of the light emitting element 21a (21b) and the decrease in the light conversion efficiency of the phosphor portion 123a (123b) can be preferably prevented.

In an embodiment of the present disclosure, a light source device includes a light source to emit a light beam, a rotator including a heat generation portion, a storage case storing the light source and the rotator, and the cooling device to cool an inside of the storage case.

The heat receiving face of the multiple first (second) heat receiving fins 143a (143b) may not be completely parallel to the rotation axis 124a (124b) of the phosphor wheel 23a (23b). When the heat receiving face is substantially parallel, the hot air flowing to the upper face of the storage case 10 can be smoothly flown along the multiple heat receiving fins without stopping.

The air with a high temperature in the storage case 10 moves to the upper part of the storage case 10. In an embodiment of the present disclosure, since the first (second) case heat receiving unit 141a (141b) is disposed on the upper face of the storage case 10, the air with a high temperature in the storage case 10 can be efficiently cooled by the in-case cooling unit 140. Thus, the temperature rise in the storage case 10 can be prevented more effectively than the temperature rise in the case where the first (second) case heat receiving unit 141a (141b) is disposed on any other inner face opposed to the circumferential face of the phosphor wheel 23a (23b) other than the upper face of the storage case 10.

Modifications will be described below.

### First Modification

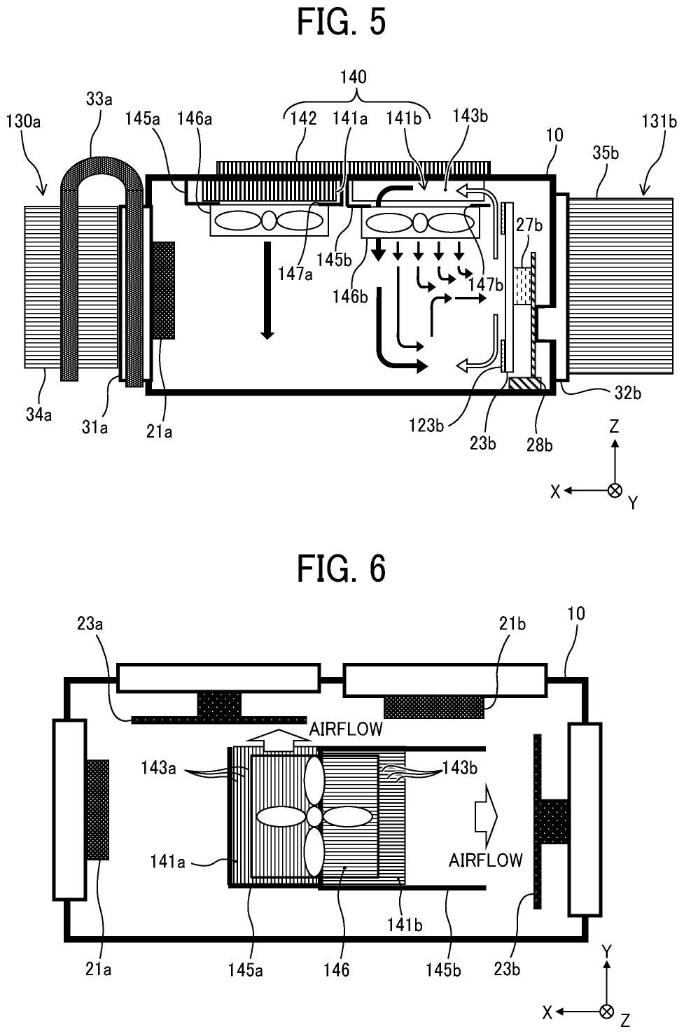

FIG. 5 is a schematic diagram illustrating a configuration of the first modification. The first modification includes fans 146a and 146b serving as airflow generators. In the first modification, the multiple first (second) heat receiving fin 143a (143b) of the first (second) case heat receiving unit 141a (141b) are covered with a duct 145a (145b). The fan 146a (146b) is attached to the duct 145a (145b) so as to cover an exhaust port 147a (147b) of the duct 145a (145b). In FIG. 5, the white arrows indicate the heated air heated by the phosphor wheel, and the black arrows indicate the cooled air cooled by the fins.

Since the fan 146a (146b) is disposed, the wind velocity of the heated air (hot air) that is heated by the phosphor wheel and flows through spaces between the multiple first (second) heat receiving fins of the first (second) case heat receiving unit 141a (141b) can be increased, and the heat exchange efficiency of the first (second) case heat receiving unit 141a (141b) can be increased. As a result, the temperature rise in the storage case 10 can be further prevented.

Further, since the duct 145a (145b) is disposed and the exhaust port of the duct 145a (145b) is covered with the intake port of the fan 146a (146b), the wind velocity of the air generated by the fan 146a (146b) can be decreased, and a decrease in the wind velocity of the air flowing the spaces between the multiple first (second) heat receiving fins of the first (second) case heat receiving unit 141a (141b) is prevented. Accordingly, the wind velocity of the air flowing between the spaces between the multiple first (second) heat receiving fins 143a (143b) of the first (second) case heat receiving unit 141a (141b) can be preferably increased, and the heat exchange efficiency of the first (second) case heat receiving unit 141a (141b) can be increased. Thus, the temperature rise of the storage case 10 can be preferably prevented. In the first modification, the duct 145a (145b) covers the overall of the multiple first (second) heat receiving fins 143a (143b), but may cover a part of the multiple first (second) heat receiving fins 143a (143b).

In an embodiment of the present disclosure, the cooling device further includes a duct to hold the airflow generator and cover at least a portion of the multiple heat receiving fins.

In FIG. 5, the fan 146a (146b) is an axial flow fan in which the intake direction and the exhaust direction are parallel to each other, but may use a sirocco fan in which the intake direction and the exhaust direction are perpendicular to each other. Using a sirocco fan allows the exhaust direction to be directed toward the phosphor wheel. Accordingly, the cooled air cooled by the first (second) case heat receiving unit 141a (141b) can be hit against the phosphor wheel 23a (23b) at a high wind velocity, and is effective in cooling the phosphor. In addition, in FIG. 5, the fan 146a (146b) is disposed so as to cover the exhaust port 147a (147b) of the duct 145a (145b) at the intake port of the fan 146a (146b), but the fan 146a (146b) may be disposed so as to cover the intake port of the duct 145a (145b) at the exhaust port 147a (147b) of the fan 146a (146b). In the case where the fan 146a (146b) is disposed so as to cover the intake port of the duct 145a (145b), it is preferable to use a sirocco fan in which the intake direction and the exhaust direction are perpendicular to each other. In the case where the sirocco fan is used, when the phosphor wheel 23a (23b) rotates, the hot air flowing in the direction perpendicular to the inner face of the storage case 10 including the case heat receiving unit can be preferably taken in and exhausted toward the first (second) case heat receiving unit 141a (141b).

In an embodiment of the present disclosure, in the cooling device, the airflow generator intakes the air in an intake direction and exhausts the air in an exhaust direction parallel to the intake direction.

The duct 145a (145b) may be removed, and the fan 146a (146b) may be attached to the storage case 10 by screwing so as to be adjacent to the multiple first (second) heat receiving fins 143a (143b) of the first (second) case heat receiving unit 141a (141b). Specifically, the fan 146a (146b) can be attached to the storage case 10 by using a spacer having a boss shape, or a cylindrical shape having a screw hole extending perpendicularly from the inner face of the storage case 10. The spacer described above may be an integral structure formed directly on the storage case 10, or may be a separate body from the storage case 10 and attached to the storage case 10 by a screw.

In an embodiment of the present disclosure, in the cooling device, in the cooling device, the airflow generator is adjacent to the multiple heat receiving fins.

In an embodiment of the present disclosure, in the cooling device, the airflow generator is fixed to the inner face of the storage case on which the multiple heat receiving fins are disposed.

Since the fan 146a (146b) is disposed near the multiple first (second) heat receiving fins 143a (143b), a decrease in the wind velocity of the air flowing the spaces between the multiple first (second) heat receiving fins 143a (143b) can be prevented even if there is no duct. Accordingly, the heat exchange efficiency of the first (second) case heat receiving unit 141a (141b) can be increased, and the temperature rise of the storage case 10 can be preferably prevented.

Further, the opening of the duct 145a (145b) covered with the fan 146a (146b) may be used as an intake port, and the opening near the phosphor wheel 23a (23b) may be used as an exhaust port, to cause the cooled air cooled by the first (second) case heat receiving unit 141a (141b) to flow through the phosphor wheel 23a (23b). In this case, it is preferable to set the air volume of the cooled air cooled by the first (second) case heat receiving unit 141a (141b) flowing through the phosphor wheel 23a (23b) to be greater than the air volume of the air flowing radially from the phosphor wheel 23a (23b) generated by the rotation of the phosphor wheel 23a (23b).

Since the cooled air cooled by the first (second) case heat receiving unit 141a (141b) flows through the phosphor wheel 23a (23b), the temperature rise in the storage case 10 and the temperature rise in the phosphor wheels 23a (23b) can be prevented. Accordingly, a decrease in the light conversion efficiency of the phosphor portion 123a (123b) can be prevented.

FIG. 6 is a schematic diagram illustrating a configuration in which a fan 146 is disposed near both the multiple first heat receiving fins 143a and the multiple second heat receiving fins 143b. Accordingly, the number of fans can be reduced as compared with the case where the fan is disposed adjacent to the multiple first heat receiving fins 143a and the fan is disposed adjacent to the multiple second heat receiving fins 143b, and the cost of the apparatus can be reduced. In addition, the light source device 1 can be reduced in size. In the configuration illustrated in FIG. 6, the fan 146a (146b) flows the cooled air cooled by the first (second) case heat receiving unit 141a (141b) to the phosphor wheels 23a (23b). However, the fan 146a (146b) may intake the air flowing the spaces between multiple first (second) heat receiving fins 143a (143b) and increase the wind velocity of the heated air (hot air) heated by the phosphor wheel 23a (23b) (first phosphor wheel and second phosphor wheel).

### Second Modification

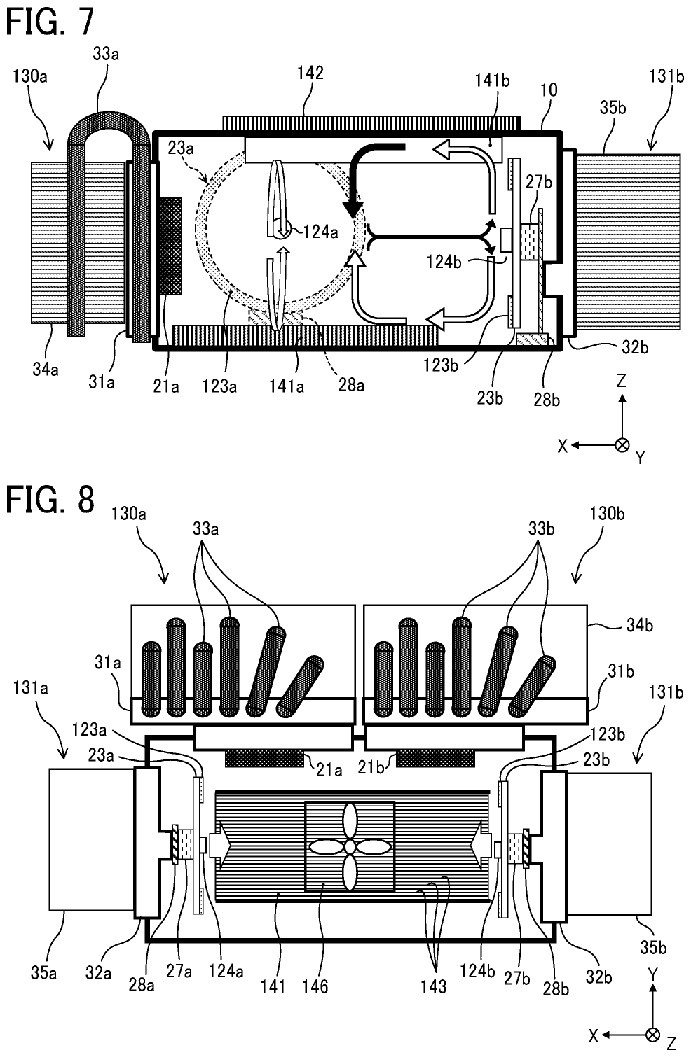

FIG. 7 is a schematic diagram illustrating a configuration of the second modification. In the second modification, the first case heat dissipation unit 141a is disposed on the bottom face of the storage case 10, and the second case heat dissipation unit 141b is disposed on the upper face of the storage case 10. As described above, since the first case heat receiving unit 141a and the second case heat receiving unit 141b are disposed on different inner faces of the storage case 10, the following advantages can be obtained. In other words, the size of the first case heat receiving unit 141a and the size of the second case heat receiving unit 141b can be increased as compared with the case where the first case heat receiving unit 141a and the second case heat receiving unit 141b are disposed on the same inner face. Accordingly, the heat receiving area of the first case heat receiving unit 141a and the heat receiving area of the second case receiving unit 141b can be increased, and the heat in the storage case 10 can be preferably exhausted to the outside of the storage case as compared with the case where the first case heat receiving unit 141a and the second case heat receiving unit 141b are disposed on the same inner face of the storage case 10. Thus, as an advantage, the temperature rise in the storage case 10 can be preferably prevented. In FIG. 7, the white arrows indicate the heated air heated by the phosphor wheel, and the black arrows indicate the cooled air cooled by the fins.

In addition, since the first case heat receiving unit 141a and the second case heat receiving unit 141b are effectively disposed on a limited space in the case where other parts are disposed on or other functions are provided with the inner face of the storage case 10, there is an advantage in increasing the degree of freedom of the configuration of the apparatus.

It is preferable that a case heat dissipation unit is also disposed on the outer face of the bottom of the storage case 10. Since the case heat dissipation unit is also disposed on the outer face of the bottom of the storage case 10, the heat received by the first case heat receiving unit 141a can be efficiently dissipated to the outside of the storage case 10, and the temperature rise in the storage case 10 can be preferably prevented. The first case heat receiving unit 141a may be disposed on the inner face of the storage case 10 opposed to the circumferential face of the phosphor wheel 23a of the first light source unit LS1, and the second case heat receiving unit 141b may be disposed on the inner face of the storage case 10 opposed to the circumferential face of the phosphor wheel 23b of the second light source unit LS2.

### Third Modification

FIG. 8 is a schematic diagram illustrating a third modification. In the third modification, the configuration includes one case heat receiving unit 141. As illustrated in FIG. 8, in the light source device 1, the storage case 10 accommodates the phosphor wheel 23a and the phosphor wheel 23b such that the rotation axis 124a of the phosphor wheel 23a is substantially parallel to the rotation axis 124b of the phosphor wheel 23b. In this configuration, as illustrated in FIG. 8, the flow direction of the hot air that flows along the upper face after flowing from the phosphor wheel 23a of the first light source unit LS1 to the upper face is opposite to the flow direction of the hot air that flows along the upper face after flowing from the phosphor wheel 23b of the second light source unit LS2 to the upper face.

In an embodiment of the present disclosure, in the light source device, the rotator includes: a first rotator including: a first heat generation portion; and a first rotation axis around which the first heat generation portion rotates; and a second rotator including: a second heat generation portion; and a second rotation axis around which the second heat generation portion rotates, the second rotation axis parallel to the first rotation axis of the first rotator, and the storage case stores the first rotator and the second rotator.

In the third modification, the multiple heat receiving fins 143 of the case heat receiving unit 141 are disposed so as to extend in a direction substantially parallel to (not intersecting with) both of the rotation axis 124a of the phosphor wheel 23a and the rotation axis 124b of the phosphor wheel 23b from near the phosphor wheel 23a of the first light source unit LS1 to near the phosphor wheel 23b of the second light source unit LS2. The multiple heat receiving fins 143 are arranged in a direction perpendicular to both the rotation axis 124a of the phosphor wheel 23a and the rotation axis 124b of the phosphor wheel 23b (horizontal direction). In the third modification, a fan 146 serving as an airflow generator is disposed substantially at the center between the phosphor wheel 23a and the phosphor wheel 23b in the rotation axis directions in the case heat receiving unit 141.

Of the hot air flowing radially along the faces of the phosphor wheels 23a and 23b, a portion of the hot air flowing to the upper face of the storage case 10 flows through the spaces between the heat receiving fins 143 of the case heat receiving unit 141 along the heat receiving fins 143. The portion of the hot air flows to the center of the case heat receiving unit 141 in the rotation axis direction while losing the heat by the multiple heat receiving fins 143, and is exhausted downward by the fan 146.

As described above, in the configuration in which the rotation axis 124a of the phosphor wheel 23a in the first light source unit LS1 is substantially parallel to the rotation axis 124b of the phosphor wheel 23b of the second light source unit LS2, the number of the case heat receiving units can be reduced to one (i.e., the case heat receiving unit 141), and the number of the fans can be also reduced to one (i.e., the fan 146). As a result, the number of the parts can be reduced and the cost of the apparatus can be decreased. In addition, as compared with the configuration in which two fans 146 are disposed, the space for disposing the fan in the storage case 10 can be reduced, and the light source device 1 can be reduced in size.

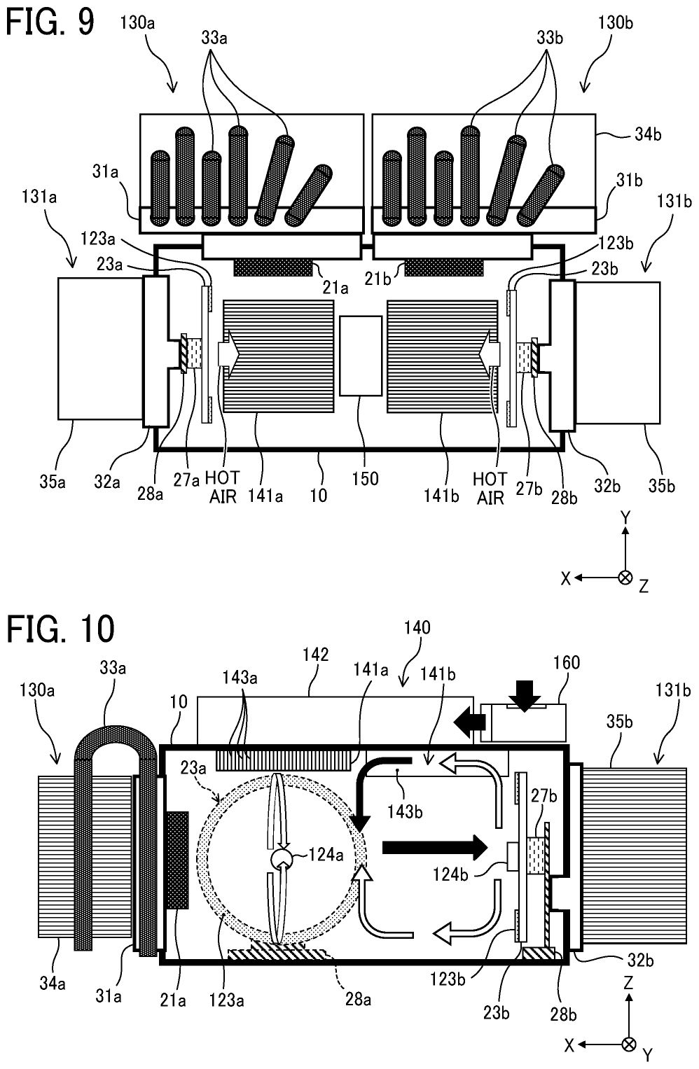

As illustrated in FIG. 9, as in an embodiment of the present disclosure, the first case heat receiving unit 141a corresponding to the phosphor wheel 23a in the first light source unit LS1 and the second case heat receiving unit 141b corresponding to the phosphor wheel 23b in the second light source unit LS2 may be disposed in the configuration. As described above, since the configuration in which the first case heat receiving unit 141a and the second case heat receiving unit 141b are disposed is used, an adjustment jig 150 that adjusts, for example, the optical lens in the storage case 10 can be disposed at the center in the rotation axis direction of the upper face of the storage case 10. In addition, a space for access to the optical lens can be obtained.

### Fourth Modification

FIG. 10 is a schematic diagram illustrating a configuration of the fourth modification. In the fourth modification, an air cooling fan 160 serving as an outside airflow generator for cooling the case heat dissipation unit 142 by air is disposed near the case heat dissipation unit 142. In the fourth modification, a sirocco fan in which the intake direction is perpendicular to the exhaust direction is used as the air cooling fan 160.

In an embodiment of the present disclosure, in the cooling device, the airflow generator intakes the air in an intake direction and exhausts the air in an exhaust direction orthogonal to the intake direction.

Since the air cooling fan 160 is disposed, the cooling air flows into the case heat dissipation unit 142, and the case heat dissipation unit 142 is cooled by air. Accordingly, the heat in the storage case 10 received by the first case heat receiving unit 141a and the second case heat receiving unit 141b can be efficiently dissipated by the case heat dissipation unit 142, and the cooling efficiency inside the case can be increased. As a result, the temperature rise inside the storage case can be preferably prevented, and the temperature rise of the light emitting element 21a (21b) and the temperature rise of the phosphor portion 123a (123b) can be prevented. Thus, a decrease in the light emission efficiency of the light emitting element 21a (21b) and the light conversion efficiency of the phosphor portion 123a (123b) can be prevented.

In the above description, the in-case cooling unit 140 cools the hot air by the phosphor wheel 23a (23b) as the rotator, but the in-case cooling unit 140 may cool the hot air by the color wheel as the rotator. The temperature of the color wheel also rises due to the heat generated when the light beam from the first light source unit LS1 and the light beam from the second light source unit LS2 are divided into a red color beam, a blue color light beam, a yellow color beam, and a green color beam, and the air near the color wheel is heated. When the color wheel rotates, the air heated by the color wheel is radially exhausted from the color wheel as hot air. Since a portion of the hot air radially exhausted from the color wheel is heated by the in-case cooling unit 140, the temperature rise in the case in which the color wheel is accommodated can be prevented.

The image projection apparatus 100 according to an embodiment of the present disclosure is used in various use, for example, business use (e.g. a projection display for a meeting or a presentation), home use, medical use (e.g., an monochromatic (grayscale) image for an X-ray imaging or a magnetic resonance imaging (MRI)), public use (e.g., a projection display to display various kinds of information, an advertisement, and a signage in public places, stores, or a transportation facility), or industrial use (e.g., a projection apparatus installed in a factory).

In an embodiment of the present disclosure, the projection apparatus 100 has a projection mode depending on the use described above, such as a color mode, a moving image mode, an image mode, a mode for a medical image to project a medical image, and a public mode to project guidance and signage out of doors or in a store. The control of the driving method or the driving amount of the light source, the power, the cooling, and the output may be automatically changed depending on the change of the mode.

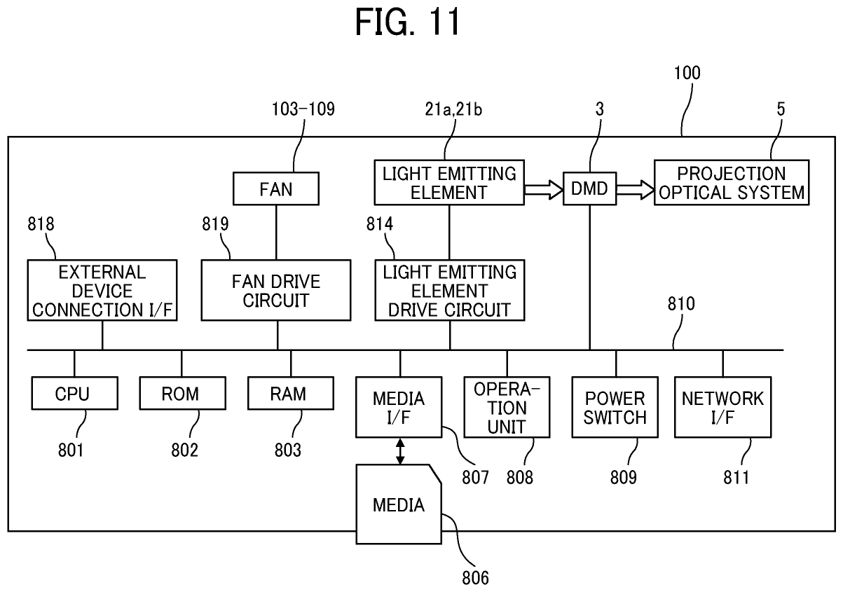

FIG. 11 is a diagram illustrating a hardware configuration of the image projection apparatus 100. As illustrated in FIG. 11, the image projection apparatus 100 includes a central processing unit (CPU) 801, a read-only memory (ROM) 802, and a random-access memory (RAM) 803. The image projection apparatus 100 also includes a media interface (I/F) 807, an operation unit 808, a bus line 810, a network interface (I/F) 811, a light emitting element drive circuit 814, an external device connection interface (I/F) 818, and a fan drive circuit 819.

The CPU 801 controls the overall operation of the image projection apparatus 100. The ROM 802 stores a program used to drive the CPU 801. The RAM 803 is used as a work area of the CPU 801. The media I/F 807 controls the media 806 such as a flash memory to read or write (store) data.

The operation unit 808 includes various keys, buttons, or LEDs, and is used to perform various operations other than ON and OFF (ON/OFF) of the power supply of the image projection apparatus 100 by the user. For example, the operation unit 808 receives instruction operations such as an adjustment of the size of the projection image, an adjustment of a color tone, a focus adjustment, and a keystone adjustment, and outputs the received operation to the CPU 801.

The power switch 809 is a switch to switch ON and OFF the power of the image projection apparatus 100. The bus line 810 is an address bus or a data bus for electrically connecting each component such as the CPU 801 in FIG. 8. The network I/F 811 is an interface to perform data communication using a communication network such as the Internet. The light emitting element drive circuit 814 turns on and off the light emitting elements 21a and 21b under the control of the CPU 801.

A personal computer (PC) is directly connected to the external device connection I/F 818 to acquire control signals and image data with the PC. The fan drive circuit 819 is connected to the CPU 801 and the fans 103 to 109, and drives and stops the fans 103 to 109 based on a control signal from the CPU 801.

When the electric power is supplied, the CPU 801 is activated based on a control program stored in the ROM 802 in advance, and provides a control signal to the light emitting element drive circuit 814 to turn on the light emitting elements 21a and 21b and also provides a control signal to the fan drive circuit 819 to rotate the fans 103 to 109 at a predetermined speed. In addition, in the image projection apparatus 100, when the power supply from the power supply circuit is started, the DMD 3 is ready to display an image, and further, power is supplied from the power supply circuit to other various components.

Further, in the image projection apparatus 100, when the power switch 809 is turned off, a power OFF signal is sent from the power switch 809 to the CPU 801, and when the CPU 801 detects the power OFF signal, the CPU 801 gives a control signal to the light emitting element drive circuit 814 to turn off the light emitting elements 21a and 21b. After a predetermined time has passed, the CPU 801 gives a control signal to the fan drive circuit 819 to stop the fans 103 to 109, and ends its own control processing, and gives an instruction to the power supply circuit to stop supplying the power supply.

As described above, the preferable embodiments of the present disclosure have been described in detail. However, the present disclosure is not limited to these embodiments, and various modifications or changes are made within the scope of the present disclosure described in the claims below.

The above-described embodiment is merely an example, and the following embodiments have their own effects.

### First Aspect

In a cooling device to exhaust heat received by multiple heat receiving fins 143 disposed on an inner face of a storage case 10 that accommodates a rotator such as a phosphor wheel that rotates and includes a heat generation portion such as a phosphor portion 123, the inner face on which the multiple heat receiving fins 143 are disposed is on an inner face parallel to a rotation axis direction of the rotator of the storage case 10, among a plurality of inner surfaces of the storage case, and a heat receiving face of the multiple heat receiving finds is substantially parallel to the rotation axis direction. When the rotator such as the phosphor wheel rotates, the following circulation airflow in the storage case 10 is generated. In other words, when the rotator rotates, air near the face of the rotator is heated by the heat generation portion of the rotator, and the air radially flows by the rotation of the rotator. As a result, a negative pressure near the center of the rotation axis of the rotator is generated, and airflow flowing toward the center of the rotation axis of the rotator along the rotation axis direction of the rotator is generated This airflow generates the negative pressure in the space of the storage case 10 opposite to a side at which the rotator is disposed. On the other hands, a hot air that has radially flowed by the rotation of the rotator hits the inner face of the storage case. The inner face is parallel to the rotation axis direction of the rotator. The air that has hit the inner face, along the inner face, flows to the space that is opposite to the side at which the rotator is disposed and has negative pressure in the rotation axis direction. The air changes the direction of the flowing to a direction perpendicular to the rotation axis direction at the opposite side of the side at which the rotator is disposed in the storage case, and moves away from the inner face. The air that has changed the direction of the flowing to the direction perpendicular to the rotation axis direction and has moved away from the inner face is changed to a direction of the flowing toward the rotator by the negative pressure near the center of the rotation axis of the rotator described above. The air that has flowed near the center of the rotation axis of the rotator is a circulating air flow radially flowing by the rotation of the rotator in the same manner as described above. In the multiple heat receiving fins in the related art, the heat receiving face (the face having the largest heat receiving area among the multiple faces of the multiple heat receiving fins) of each of the multiple heat receiving fins is perpendicular to the rotation axis direction, and the multiple heat receiving fins are arranged in the rotation axis direction. The hot air that has flowed, along the inner face, in the rotation axis direction toward the space that is opposite to the side at which the rotator is disposed hits the heat receiving fin disposed at a position closest to the rotator and stays. Accordingly, the hot air is less likely to flow to the heat receiving fins disposed at a position away from the rotator. As a result, the heat receiving efficiency of the heat receiving fin disposed at a position away from the rotator was lower. In contrast, in the first aspect, since the heat receiving faces of the multiple heat receiving fins are substantially parallel to the direction of the rotation axis of the rotator, the air with high temperature that has flowed in the rotation axis direction flows along the heat receiving faces of the multiple heat receiving fins toward the space that is opposite to the side at which the rotator is disposed in the storage case along the inner peripheral face. As a result, the multiple heat receiving fins 143 can preferably receive the heat of the hot heat flowing along the inner face, and the heat receiving efficiency can be increased.

### Second Aspect

The cooling device according to the first aspect includes an air flow generator such as a fan 146 that flows air to the multiple heat receiving fins 143 in the storage case. Accordingly, as described in the first modification of the present disclosure, the wind velocity of the air flowing along the multiple heat receiving fins can be increased as compared with the case where there is no airflow generator. As a result, the heat exchange efficiency of the case heat receiving unit can be increased and the temperature rise of the storage case 10 can be preferably prevented.

In an embodiment of the present disclosure, the cooling device according to the further includes an airflow generator in the storage case to blow air to the multiple heat receiving fins.

### Third Aspect

In the cooling device according to the second aspect, the airflow generator such as a fan is disposed near to the multiple heat receiving fins. Accordingly, as described in the first modification of the present disclosure, a decrease in the wind velocity of the air that is generated by the airflow generator such as a fan and flows to the multiple heat receiving fins can be prevented. As a result, the wind velocity of the air flowing between the spaces between the multiple heat receiving fins can be preferably increased, and the heat exchange efficiency of the multiple heat receiving fins can be increased. Thus, the temperature rise of the storage case can be preferably prevented.

### Fourth Aspect

In the cooling device according to the second or third aspect, the airflow generator such as a fan has an intake direction and an exhaust direction parallel to each other. Accordingly, as described in the first modification of the present disclosure, an axial fan in which the intake direction and the exhaust direction are parallel to each other can be used as the airflow generator.

### Fifth Aspect

In the cooling device according to the second or third aspect, the airflow generator has an intake direction and an exhaust direction perpendicular to each other. Accordingly, as described in the first modification of the present disclosure, a sirocco fan in which the intake direction and the exhaust direction are perpendicular to each other can be used as the airflow generator.

### Sixth Aspect

In the cooling device according to any one of the second to fifth aspects, the airflow generator such as a fan is fixed to the inner face of the storage case on which the multiple heat receiving fins are disposed. Accordingly, the airflow generator such as a fan can be disposed adjacent to the multiple heat receiving fins.

### Seventh Aspect

In the cooling device according to any one of the second to fifth aspects, the airflow generator includes a duct that covers at least a part of the multiple heat receiving fins, and the duct holds the airflow generator. Accordingly, as described in the first modification of the present disclosure, the airflow generator such as a fan can be disposed so as to cover an intake port or an exhaust port of the duct. Since the airflow generator such as fan is disposed so as to cover the intake port or the exhaust port of the duct, a decrease in the wind velocity of the air that flows through the multiple heat receiving fins by the airflow generator such as a fan can pre prevented. As a result, the heated air heated by the rotator can be efficiently cooled by the heat receiving portion, and the temperature rise in the storage case can be preferably prevented.

### Eighth Aspect

In the cooling device according to any one of the second to seventh aspects, the airflow generator such as a fan generates airflow toward the multiple light receiving fins from the rotator such as a phosphor wheel in the storage case. Accordingly, as described in the first modification of the present disclosure, a hot wind heated by the rotator can be preferably flowed to the heat receiving fins and can be efficiently cooled by the multiple heat receiving fins.

### Ninth Aspect

In the cooling device according to any one of the second to seventh aspects, the airflow generator such as a fan generates airflow toward the rotator such as a phosphor wheel from the multiple heat receiving fins in the storage case. Accordingly, as described in the first modification of the present disclosure, the multiple heat receiving fins cool the hot air in the storage case, the cooled air cooled by the multiple heat receiving fins flows to the rotator such as a phosphor wheel, and the phosphor wheel can be cooled. As a result, the temperature rise of the phosphor wheel 23a (23b) can be prevented, and the decrease in the light conversion efficiency of the phosphor portion 123a (123b) can be prevented.

### Tenth Aspect

In the cooling device according to any one of the first to ninth aspects, the multiple heat dissipating fins are disposed on an outer face of a wall of the storage case 10. The wall has the inner face on which the multiple heat receiving fins are disposed. Accordingly, as described in an embodiment of the present disclosure, the heat dissipation area can be increased, and the heat dissipation efficiency can be increased as compared with the case where the heat received by the multiple heat receiving fins of the storage case is exhausted to the outside of the storage case. As a result, the temperature rise of the multiple heat receiving fins can be prevented, the multiple heat receiving fins can preferably take the heat in the storage case, and the temperature rise in the storage case can preferably be prevented.

### Eleventh Aspect

The cooling device according to the tenth aspect further includes an outer airflow generator such as an air cooling fan to flow air toward the multiple heat dissipation fins. Accordingly, as described in the fourth modification of the present disclosure, the multiple heat dissipation fins are cooled by airflow generated by the outer airflow generator such as an air cooling fan. As a result, the multiple heat dissipation fins can efficiently cool the heat received by the multiple heat receiving fins in the storage case, and the cooling efficiency in the storage case can be increased. Thus, the temperature rise in the storage case can be preferably prevented.

### Twelfth Aspect

The cooling device according to any one of the first to eleventh aspects further includes a cooling unit to dissipate heat of a light-emitting-and-heat-generating portion such as the light emitting element 21a (21b) (i.e., light emitter) accommodated in the storage case 10 to an outside of the storage case to cool the light-emitting-and-heat-generating portion. Accordingly, as described in an embodiment of the present disclosure, the temperature rise of the light emitting element 21a (21b) can be prevented, and the decrease in the light emitting efficiency of the light emitting element 21a (21b) can be prevented.

### Thirteenth Aspect

The cooling device according to any one of the first to twelfth aspects further includes a motor cooling unit to dissipate heat from a motor that rotates and drives the rotator such as a phosphor wheel to the outside of the storage case to cool the motor. Accordingly, as described in an embodiment of the present disclosure, the temperature of the motor such as a drive motor can be cooled such that the temperature of the motor does not reach the limitation of the specification.

### Fourteenth Aspect

The cooling device according to any one of the first to thirteenth aspects further includes a storage case cooling device (i.e., storage case cooler) such as a fan to blow cool air to the storage case 10. Accordingly, as described in an embodiment of the present disclosure, the cool air by the storage case cooling device can cool the storage case 10, and the heat in the storage case 10 can be preferably exhausted to the outside of the storage case 10. Thus, the temperature rise in the storage case 10 can be preferably prevented.

### Fifteenth Aspect

A light source device includes a light source such as a light emitting element, a rotator such as a phosphor wheel that includes a heat generation portion such as a phosphor portion and rotates, a storage case 10 that accommodates the light source and the rotator, and the cooling device according to any one of the first to fourteenth aspects, such as an in-case cooling unit 140, to cool the inside of the storage case. As a result, the temperature rise inside the storage case can be prevented, and the temperature rise of the light source such as a light emitting element and the temperature rise of the rotator can be prevented. Thus, a decrease in the light emission efficiency of the light emitting element can be preferably prevented.

### Sixteenth Aspect

In the light source device according to the fifteenth aspect, the heat generation portion is a light-receiving-and-heat-generating portion (i.e., heat receiving portion) such as a phosphor portion to receive the light beam from the light source such as an light emitting element and generate heat. Accordingly, as described in an embodiment of the present disclosure, the cooling device can preferably cool the air in the storage case heated by the heat generated by the light-receiving-and-heat-generating portion.

### Seventeenth Aspect

In the light source device according to the sixteenth aspect, the light-receiving-and-heat-generating portion is a phosphor portion. Accordingly, as described in an embodiment of the present disclosure, since the temperature rise in the storage case can be prevented by the cooling device, the temperature rise of the phosphor portion can be prevented, and the decrease in the wavelength conversion efficiency of the phosphor portion can be prevented Eighteenth Aspect

In the light source device according to any one of the fifteenth to seventeenth aspects, the rotator such as a phosphor wheel is made of a material having a higher thermal conductivity than a thermal conductivity of the heat generation portion such as the phosphor portion. Accordingly, as described in an embodiment of the present disclosure, the heat from the heat generation portion such as a phosphor wheel moves to a main body of the rotator, and the heat of the heat generation portion can be dissipated from the main body of the rotator. As a result, the temperature rise of the heat generation portion can be prevented.

### Nineteenth Aspect

In the light source device according to any one of the fifteenth to eighteenth aspects, the storage case 10 accommodates a first rotator such as the phosphor wheel 23a having the heat generation portion such as the phosphor portion 123a in the first light source unit LS1 and a second rotator such as the phosphor wheel 23b having the heat generation portion such as the phosphor portion 123b in the first light source unit LS2. The first rotator and the second rotator rotate, and the rotation axis of the first rotator and the rotation axis of the second rotator are substantially perpendicular to each other. Accordingly, since the hot wind radially flowing from at least one of the first rotator or the second rotator flows through the multiple heat receiving fins, the hot wind can be cooled

### Twentieth Aspect

In the light source device according to any one of the fifteenth to eighteenth aspects, the storage case 10 accommodates a first rotator such as the phosphor wheel 23a having the heat generation portion such as the phosphor portion 123a in the first light source unit LS1 and a second rotator such as the phosphor wheel 23b having the heat generation portion such as the phosphor portion 123b in the first light source unit LS2. The first rotator and the second rotator rotate, and the rotation axis of the first rotator and the rotation axis of the second rotator are substantially parallel to each other. Accordingly, as described in the third embodiment of the present disclosure, since the hot wind radially flowing from the first rotator and the hot wind radially flowing from the second rotator flow through the multiple heat receiving fins, both the hot winds can be cooled

### Twenty-first Aspect

The light source device according to the nineteenth or twentieth aspect further includes multiple first heat receiving fins disposed on the inner face of the storage case parallel to the rotation axis of the first rotator such as the phosphor wheel 23a in the first light source unit LS1 and the heat receiving face of the multiple first heat receiving fins is parallel to the rotation axis of the first rotator and multiple second heat receiving fins disposed on the inner face of the storage case parallel to the rotation axis of the second rotator such as the phosphor wheel 23b in the second light source unit LS2 and the heat receiving face of the multiple first heat receiving fins is parallel to the rotation axis of the second rotator. Accordingly, since the hot wind radially flowing from the first rotator flows through the multiple first heat receiving fins 143a, the hot wind can be preferably cooled. In addition, since the hot wind radially flowing from the second rotator flows through the multiple second heat receiving fins 143b, the hot wind can be preferably cooled, As described above, since the multiple first heat receiving fins and the multiple second heat receiving fins can cool portions of the hot air radially flowing from the first rotator and the second rotator, respectively, the temperature rise in the storage case 10 can be preferably prevented.

### Twenty-Second Aspect

In the light source device according to the twentieth aspect or twenty-first aspect, the multiple first heat receiving fins 143a and the multiple second heat receiving fins 143b are disposed on the same inner face of the storage case 10. Accordingly, since the multiple heat dissipation fins are disposed on the outer face of the storage case having the inner face on which the multiple first heat receiving fins 143a and the multiple second heat receiving fins 143b are disposed, the heat from the multiple first heat receiving fins 143a and the multiple second heat receiving fins 143b can be dissipated through the multiple heat dissipation fins. Further, as illustrated in FIG. 9, the space for disposing the adjustment jig 150 that adjusts the optical lens in the storage case 10 or accessing the optical lens can be obtained between the multiple first heat receiving fins 143a and the multiple second heat receiving fins 143b.

### Twenty-Third Aspect

In the light source device according to the twenty-first aspect, the multiple first heat receiving fins 143a and the multiple second heat receiving fins 143b are disposed on different inner faces of the storage case 10 from each other. Accordingly, as described in the second modification of the present disclosure, the length of the multiple first heat receiving fins 143a or the length of the multiple second heat receiving fins 143b can be increased, or the number of the first heat receiving fins 143a or the number of the second heat receiving fins 143b can be increased as compared with the case where the multiple first heat receiving fins 143a and the multiple second heat receiving fins 143b are disposed on the same inner face of the storage case 10. As a result, the heat in the storage case 10 can be preferably exhausted to the outside of the storage case 10 as compared with the case where the multiple first heat receiving fins 143a and the multiple second heat receiving fins 143b are disposed on the same inner face of the storage case 10. Thus, the temperature rise in the storage case 10 can be preferably prevented.

### Twenty-Fourth Aspect

In the light source device according to the twentieth aspect, the heat receiving fins are adjacent to both the first rotator and the second rotator. Accordingly, as described in the third modification of the present disclosure, since the hot wind radially flowing from the first rotator and the hot wind radially flowing from the second rotator flow through the multiple heat receiving fins, both the hot winds can be cooled by the multiple heat receiving fins.

### Twenty-Fifth Aspect

The light source device according to the twenty-second aspect further includes an airflow generator such as the fan 146 that is disposed near both the multiple first heat receiving fins 143a and the multiple second heat receiving fins 143b and flows air in the storage case to both the multiple first heat receiving fins 143a and the multiple second heat receiving fins 143b. Accordingly, as described in FIG. 6, the number of the airflow generators can be reduced, and the cost of the light source device can be reduced as compared with the case where the airflow generator corresponding to the multiple first heat receiving fins 143a and the airflow generator corresponding to the multiple second heat receiving fins 143b are disposed. Further, since a space on which only one airflow generator is disposed can be obtained, the size of the light source device can be reduced as compared with the case where the airflow generator corresponding to the multiple first heat receiving fins and the airflow generator corresponding to the multiple second heat receiving fins are disposed.

### Twenty-Sixth Aspect

The light source device according to any one of the twenty-first to twenty-third aspects further includes a first airflow generator such as a fan 146a to flow air in the storage case 10 to the multiple first heat receiving fins 143a and a second airflow generator such as a fan 146b to flow air in the storage case 10 to the multiple second heat receiving fins 143b. Accordingly, as described in the first modification, the wind velocity of a portion of the hot air that has radially flowed from the multiple first heat receiving fins 143a and flows along the multiple first heat receiving fins 143a can be increased, and the heat exchange efficiency of the multiple first heat receiving fins 143a can be increased. Further, similarly, the wind velocity of a portion of the hot air that has radially flowed from the multiple second heat receiving fins 143b and flows along the multiple second heat receiving fins 143b can be increased, and the heat exchange efficiency of the multiple second heat receiving fins 143b can be increased. Thus, the temperature rise in the storage case 10 can be preferably prevented.

### Twenty-Seventh Aspect

A image projection apparatus includes the light source 1 according any one of the fifteenth to twenty-sixth aspects, a light homogenizer such as a light tunnel 2 that homogenizes the incident light beam from the light source 1 and emits the homogenized light beam, an image display element such as DMD3 that modulate the homogenized light beam from the light homogenizer to forms an image, and a projection optical unit 5 (projection optical system) to magnify the image and project the image to a projection screen. Accordingly, the decrease in the light emitting efficiency of the light emitting elements or the decrease in the wavelength conversion efficiency of the of the light source device can be prevented, and the image with high illuminance can be projected to the projection face.

### Twenty-Eighth Aspect

A cooling device includes a rotator including a heat generation portion to generate heat, and a rotation axis around which the heat generation portion rotates, multiple heat receiving fins each having a heat receiving face extending in an axial direction of the rotation axis of the rotator, and a storage case storing the rotator and the multiple heat receiving fins. The multiple heat receiving fins are on an inner face of the storage case and arrayed in an array direction orthogonal to the axial direction.

### Twenty-Nineth Aspect

The cooling device according to the twenty-eighth aspect, further includes an airflow generator in the storage case to blow air to the multiple heat receiving fins.

### Thirtieth Aspect

In the cooling device according to the twenty-nineth aspect, the airflow generator is adjacent to the multiple heat receiving fins.

### Thirty-First Aspect

In the cooling device according to the twenty-nineth or thirtieth aspect, the airflow generator intakes the air in an intake direction and exhausts the air in an exhaust direction parallel to the intake direction.

### Thirty-Second Aspect

In the cooling device according to the twenty-nineth or thirtieth aspect, the airflow generator intakes the air in an intake direction and exhausts the air in an exhaust direction orthogonal to the intake direction.

### Thirty-Third Aspect

In the cooling device according to any one of the twenty-nineth to thirty-second aspects, the airflow generator is fixed to the inner face of the storage case on which the multiple heat receiving fins are disposed.

### Thirty-Fourth Aspect

The cooling device according to any one of the twenty-nineth to thirty-second aspects further includes a duct to hold the airflow generator and cover at least a portion of the multiple heat receiving fins.

### Thirty-Fifth Aspect

The cooling device according to the twenty-eighth to thirty fourth aspects further includes multiple heat dissipation fins on an outer face of the storage case. The storage case has a wall having the outer face and the inner face opposite to the outer face.

### Thirty-Sixth Aspect

The cooling device according to the thirty-fifth aspect further includes an outer airflow generator to blow air to the multiple heat dissipation fins.

### Thirty-Seventh Aspect

The cooling device according to any one of the twenty-eighth to thirty-sixth aspects further includes a light emitter in the storage case to emit light and a cooler to dissipate heat generated from the light emitter to an outside of the storage case.

### Thirty-Eighth Aspect

The cooling device according to any one of the twenty-eighth to thirty-seventh aspects further includes a motor to rotate the rotation axis to rotate the rotator and a motor cooler to dissipate heat generated from the motor to an outside of the storage case.

### Thirty-Nineth Aspect

The cooling device according to any one of the twenty-eighth to thirty eighth aspects further includes a storage case cooler to blow cool air to the storage case.

### Fortieth

A light source device includes a light source to emit a light beam, a rotator including a heat generation portion, a storage case storing the light source and the rotator, and the cooling device to cool an inside of the storage case.

### Forty-First Aspect

In the light source device according to the fortieth aspect, the heat generation portion is a light receiving portion to receive the light beam emitted from the light source to generate heat.

### Forty-Second Aspect

In the light source device according to the forty-first aspect, the light receiving portion includes a phosphor portion.

### Forty-Third Aspect

In the light source device according to any one of the fortieth to forty-second aspects, the rotator has a wheel made of a material having a thermal conductivity higher than a thermal conductivity of the heat generation portion.

### Forty-Fourth Aspect

In the light source device according to any one of the fortieth to forty-third aspects, the rotator includes: a first rotator including: a first heat generation portion; and a first rotation axis around which the first heat generation portion rotates; and a second rotator including: a second heat generation portion; and a second rotation axis around which the second heat generation portion rotates, the second rotation axis perpendicular to the first rotation axis of the first rotator, and the storage case stores the first rotator and the second rotator.

### Forty-Fifth Aspect

In the light source device according to any one of the fortieth to forty-third aspects, the rotator includes: a first rotator including: a first heat generation portion; and a first rotation axis around which the first heat generation portion rotates; and a second rotator including: a second heat generation portion; and a second rotation axis around which the second heat generation portion rotates, the second rotation axis parallel to the first rotation axis of the first rotator, and the storage case stores the first rotator and the second rotator.

### Forty-Sixth Aspect

The light source device according to the forty-fourth or forty-fifth aspect, the multiple heat receiving fins includes: first multiple heat receiving fins each having a first heat receiving face parallel to the first rotation axis of the first rotator; and second multiple heat receiving fins each having a second heat receiving face parallel to the second rotation axis of the second rotator, the first multiple heat receiving fins are disposed on an inner face of the storage case parallel to the first rotation axis of the first rotator, and the second multiple heat receiving fins are disposed on an inner face of the storage case parallel to the second rotation axis of the second rotator.

### Forty-Seventh Aspect

An image projection apparatus includes the light source device, a light homogenizer to homogenize the light beam emitted from the light source device, an image display element to modify the light beam emitted from the light homogenizer and to form an image, and a projection optical system to magnify the image and project the image to a projection face.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

Any one of the above-described operations may be performed in various other ways, for example, in an order different from the one described above.

Each of the functions of the described embodiments may be implemented by one or more processing circuits or circuitry. Processing circuitry includes a programmed processor, as a processor includes circuitry. A processing circuit also includes devices such as an application specific integrated circuit (ASIC), a digital signal processor (DSP), a field programmable gate array (FPGA), and conventional circuit components arranged to perform the recited functions.

1. A cooling device comprising:
a rotator including:
a heat generation portion to generate heat; and
a rotation axis around which the heat generation portion rotates;
multiple heat receiving fins each having a heat receiving face extending in an axial direction of the rotation axis of the rotator; and
a storage case storing the rotator and the multiple heat receiving fins,
wherein the multiple heat receiving fins are:
on an inner face of the storage case; and
arrayed in an array direction orthogonal to the axial direction.

2. The cooling device according to claim 1, further comprising an airflow generator in the storage case to blow air to the multiple heat receiving fins.

3. The cooling device according to claim 2,
wherein the airflow generator is adjacent to the multiple heat receiving fins.

4. The cooling device according to claim 2,
wherein the airflow generator intakes the air in an intake direction and exhausts the air in an exhaust direction parallel to the intake direction.

5. The cooling device according to claim 2,
wherein the airflow generator intakes the air in an intake direction and exhausts the air in an exhaust direction orthogonal to the intake direction.

6. The cooling device according to claim 2,
wherein the airflow generator is fixed to the inner face of the storage case on which the multiple heat receiving fins are disposed.

7. The cooling device according to claim 2, further comprising a duct to:
hold the airflow generator; and
cover at least a portion of the multiple heat receiving fins.

8. The cooling device according to claim 1, further comprising multiple heat dissipation fins on an outer face of the storage case,
wherein the storage case has a wall having the outer face and the inner face opposite to the outer face.

9. The cooling device according to claim 8, further comprising an outer airflow generator to blow air to the multiple heat dissipation fins.

10. The cooling device according to claim 1, further comprising:
a light emitter in the storage case to emit light; and
a cooler to dissipate heat generated from the light emitter to an outside of the storage case.

11. The cooling device according to claim 1, further comprising:
a motor to rotate the rotation axis to rotate the rotator; and
a motor cooler to dissipate heat generated from the motor to an outside of the storage case.

12. The cooling device according to claim 1, further comprising a storage case cooler to blow cool air to the storage case.

13. A light source device comprising:
a light source to emit a light beam;
a rotator including a heat generation portion;
a storage case storing the light source and the rotator; and
the cooling device according to claim 1 to cool an inside of the storage case.

14. The light source device according to claim 13,
wherein the heat generation portion is a light receiving portion to receive the light beam emitted from the light source to generate heat.

15. The light source device according to claim 14,
wherein the light receiving portion includes a phosphor portion.

16. The light source device according to claim 13,
wherein the rotator has a wheel made of a material having a thermal conductivity higher than a thermal conductivity of the heat generation portion.

17. The light source device according to claim 13,
wherein the rotator includes:
a first rotator including:
a first heat generation portion; and
a first rotation axis around which the first heat generation portion rotates; and
a second rotator including:
a second heat generation portion; and
a second rotation axis around which the second heat generation portion rotates, the second rotation axis perpendicular to the first rotation axis of the first rotator, and
the storage case stores the first rotator and the second rotator.

18. The light source device according to claim 13,
wherein the rotator includes:
a first rotator including:
a first heat generation portion; and
a first rotation axis around which the first heat generation portion rotates; and
a second rotator including:
a second heat generation portion; and
a second rotation axis around which the second heat generation portion rotates, the second rotation axis parallel to the first rotation axis of the first rotator, and
the storage case stores the first rotator and the second rotator.

19. The light source device according to claim 18,
wherein the multiple heat receiving fins includes:
first multiple heat receiving fins each having a first heat receiving face parallel to the first rotation axis of the first rotator; and
second multiple heat receiving fins each having a second heat receiving face parallel to the second rotation axis of the second rotator,
the first multiple heat receiving fins are disposed on an inner face of the storage case parallel to the first rotation axis of the first rotator, and
the second multiple heat receiving fins are disposed on an inner face of the storage case parallel to the second rotation axis of the second rotator.

20. An image projection apparatus comprising:
the light source device according to claim 13;
a light homogenizer to homogenize the light beam emitted from the light source device;
an image display element to modify the light beam emitted from the light homogenizer and to form an image; and
a projection optical system to magnify the image and project the image to a projection face.
